(19) United States
(12) Patent Application Publication
(10) Pub. No.: US 2024/0395884 A1
(43) Pub. Date: Nov. 28, 2024

(54) RADIO FREQUENCY DEVICE

(71) Applicant: UNITED MICROELECTRONICS CORP., Hsin-Chu City (TW)

(72) Inventor: Po-Yu Yang, Hsinchu City (TW)

(73) Assignee: UNITED MICROELECTRONICS CORP., Hsin-Chu City (TW)

(21) Appl. No.: 18/216,588

(22) Filed: Jun. 29, 2023

(30) Foreign Application Priority Data
May 26, 2023 (TW) 112119661

(51) Int. Cl. H01L 29/423; H01L 27/12

(52) U.S. Cl. CPC H01L 29/42376; H01L 27/1203; H01L 29/42364

(57) ABSTRACT

A radio-frequency (RF) device includes a first gate structure extending along a first direction on a substrate, a spacer around the first gate structure, a first source/drain region adjacent to two sides of the first gate structure, a first body region extending along a second direction opposite to the first gate structure, and a first dielectric layer extending along the second direction between the first gate structure and the first body region. Preferably, the first gate structure includes a T-shape, the T-shape includes a vertical portion and a horizontal portion, and the first body region is opposite to the vertical portion.

### BACKGROUND OF THE INVENTION

### 1. Field of the Invention

The invention relates to a semiconductor device, and more particularly, to a radio frequency (RF) device.

### 2. Description of the Prior Art

As technology evolves, wireless communication is an important part of human life. Various electronic devices, such as smart phones, smart wearable devices, tablets, etc., utilize wireless radio frequency (RF) systems to transmit and receive wireless signals. A low noise amplifier (LNA) and a power amplifier (PA) are necessary amplifying circuits in the wireless RF system. In order to achieve better performance (e.g., linearity), the amplifying circuit requires an appropriate bias point. A common way is to electrically connect a biasing module to the amplifying circuit, so as to utilize the biasing module for providing a bias point for the amplifying circuit.

Nevertheless in conventional fabrication of RF devices, the relationship between gain and frequency measured after the fabrication process is often affected by the fabrication parameters to produce abnormal values that further induce noise in the substrate. Hence, how to improve current RF device structures for resolving this issue has become an important task in this field.

### SUMMARY OF THE INVENTION

According to an embodiment of the present invention, a radio-frequency (RF) device includes a first gate structure extending along a first direction on a substrate, a spacer around the first gate structure, a first source/drain region adjacent to two sides of the first gate structure, a first body region extending along a second direction opposite to the first gate structure, and a first dielectric layer extending along the second direction between the first gate structure and the first body region. Preferably, the first gate structure includes a T-shape, the T-shape includes a vertical portion and a horizontal portion, and the first body region is opposite to the vertical portion.

According to another aspect of the present invention, a radio-frequency (RF) device includes a gate structure on a substrate, a dielectric layer adjacent to one side of the gate structure, a body region adjacent to the dielectric layer in the substrate, and an interlayer dielectric (ILD) layer around the dielectric layer and the gate structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 illustrate a method for fabricating a RF device according to an embodiment of the present invention.

FIG. 10 illustrates a top view of a RF device according to an embodiment of the present invention.

FIG. 11 illustrates a top view of a RF device according to an embodiment of the present invention.

FIG. 12 illustrates a top view of a RF device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

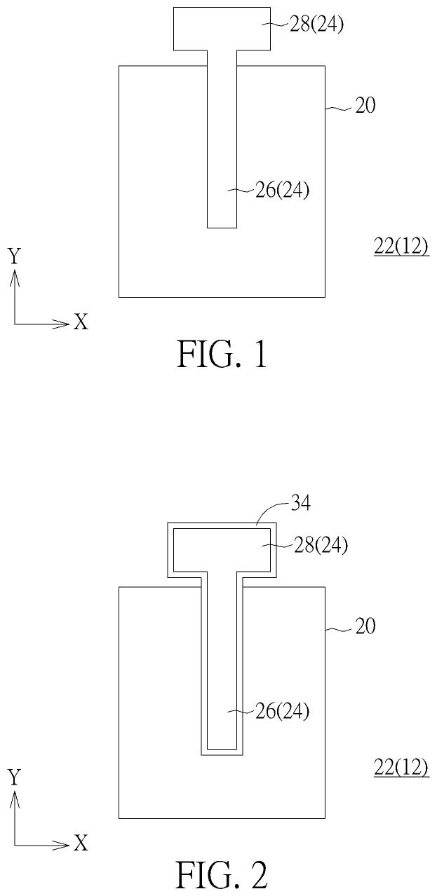

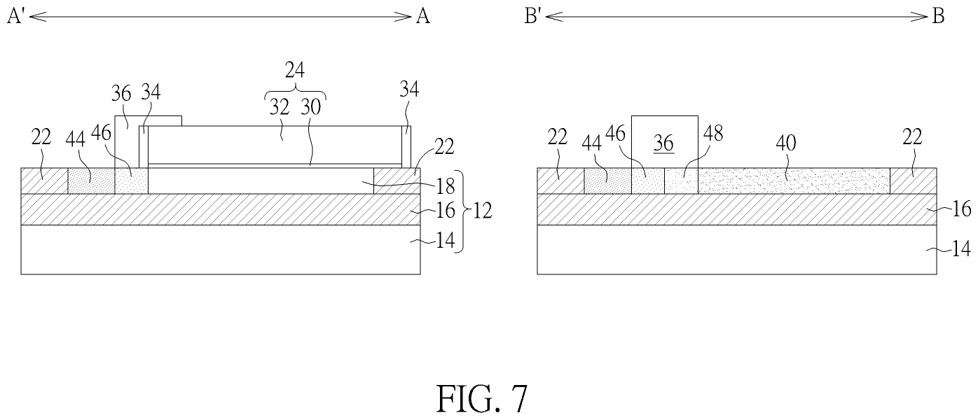

Referring to FIGS. 1-9, FIGS. 1-9 illustrate a method for fabricating a RF device according to an embodiment of the present invention, in which FIGS. 1-6 are top views for fabricating the RF device according to an embodiment of the present invention and FIGS. 7-9 are cross-section views for fabricating the semiconductor device following FIG. 6. A shown in FIGS. 1 and 7, a substrate 12 made of silicon material such as a silicon-on-insulator (SOI) substrate is provided, in which the substrate 12 includes a first semiconductor layer 14, an insulating layer 16 disposed on the first semiconductor layer 14, and a second semiconductor layer 18 disposed on the insulating layer 16. In this embodiment, the first semiconductor layer 14 and the second semiconductor layer 18 could be made of same material or different material and could both be made of material including but not limited to for example silicon, germanium, or silicon germanium (SiGe). The insulating layer 16 disposed between the first semiconductor layer 14 and second semiconductor layer 18 preferably includes SiO₂, but not limited thereto.

It should be noted that the substrate 12 in this embodiment pertains to be a SOI substrate, according to other embodiment of the present invention, the substrate 12 could also be a semiconductor substrate made of a silicon substrate, an epitaxial silicon substrate, or a silicon carbide (SiC) substrate, which are all within the scope of the present invention. Next, an active are 20 is defined on the substrate 12, and then part of the second semiconductor layer 18 outside the active area 20 is removed to form a shallow trench isolation (STI) 22 around the active area 20 or the remaining second semiconductor layer 18, in which an active device or TF device is to be fabricated on the second semiconductor layer 18 surrounded by the STI 22 in the later process.

Next, a gate structure 24 is formed on the substrate 12. From a top view perspective, the gate structure 24 is extending along a first direction such as Y-direction on the substrate 12, in which the gate structure 24 overall includes a T-shape, the T-shape further includes a vertical portion 26 and a horizontal portion 28, the vertical portion 26 is extending along the Y-direction on the STI 22 and the active area 20, and the horizontal portion 28 is extending along the X-direction on the STI 22 outside the active area 20.

From a cross-section perspective shown in FIG. 7, the formation of the gate structure 24 could be accomplished by a gate first process, a high-k first approach from gate last process, or a high-k last approach from gate last process. Since this embodiment pertains to a high-k last approach, a gate dielectric layer 30 or interfacial layer made of silicon oxide, a gate material layer 32 preferably made of polysilicon, and a selective hard mask (not shown) could be formed sequentially on the substrate 12, and a pattern transfer process is then conducted by using a patterned resist (not shown) as mask to remove part of the gate material layer 32 and part of the gate dielectric layer 30 through single or multiple etching processes. After stripping the patterned resist, a gate structure 24 composed of a patterned gate dielectric layer 30 and patterned gate material layer 32 is formed on the substrate 12.

Next, as shown in FIG. 2, at least a spacer 34 is formed on sidewalls of the gate structure 24. In this embodiment, the spacer 34 could be a single spacer or a composite spacer as the spacer 34 could further include an offset spacer (not shown) and a main spacer (not shown). The offset spacer and the main spacer are preferably made of different materials while the offset spacer and main spacer could all be selected from the group consisting of SiO₂, SiN, SiON, and SiCN, but not limited thereto.

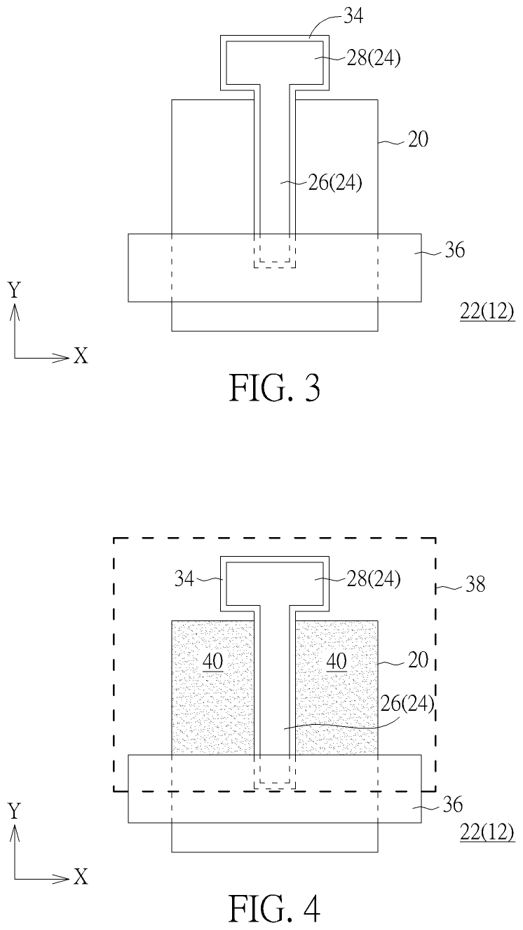

Next, as shown in FIG. 3, a dielectric layer 36 is formed extending along the X-direction on the active area 20 and covering part of the gate structure 24 on the substrate 12. In this embodiment, the dielectric layer 36 could be made of dielectric material such as silicon oxide or silicon nitride, but not limited thereto.

Next, as shown in FIG. 4, a patterned mask (not shown) such as a patterned resist is formed to cover part of the dielectric layer 36 and the substrate 12 under the dielectric layer 36, and then an ion implantation process is conducted to form a doped region in the region 38 or the substrate 12 adjacent to two sides of the vertical portion 26 of the gate structure 24 serving as a source/drain region 40. The patterned mask is then removed thereafter. In this embodiment, the ion implantation process conducted at this stage preferably implants n-type dopants into the substrate 12 such that the source/drain region 40 formed is preferably a n+ region.

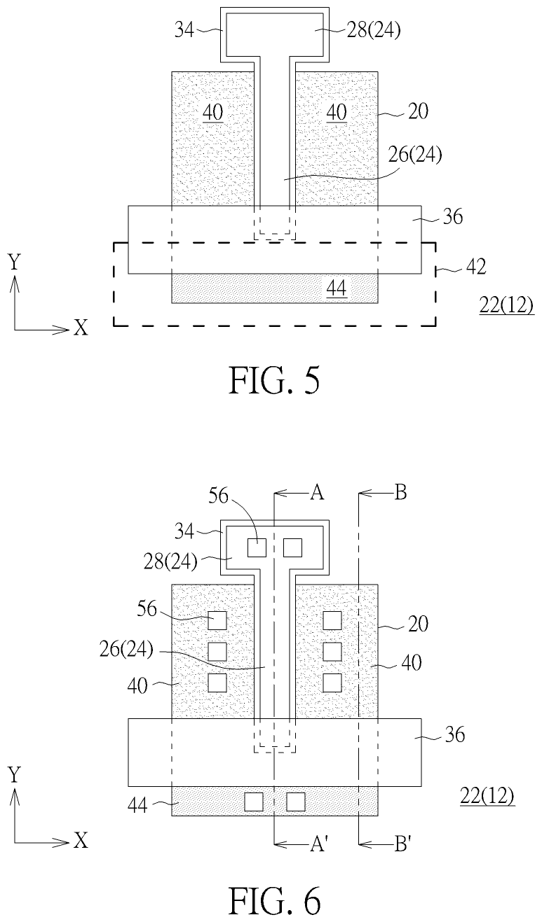

Next, as shown in FIG. 5, another patterned mask (not shown) such as a patterned resist is formed to cover part of the dielectric layer 36 and the substrate 12 and gate structure 24 above the dielectric layer 36, and then an ion implantation process is conducted to form another doped region in the region 42 or the substrate 12 below the dielectric layer 36 serving as a body region 44. In this embodiment, the ion implantation process conducted at this stage preferably implants p-type dopants into the substrate 12 so that the body region 44 is preferably a p+ region.

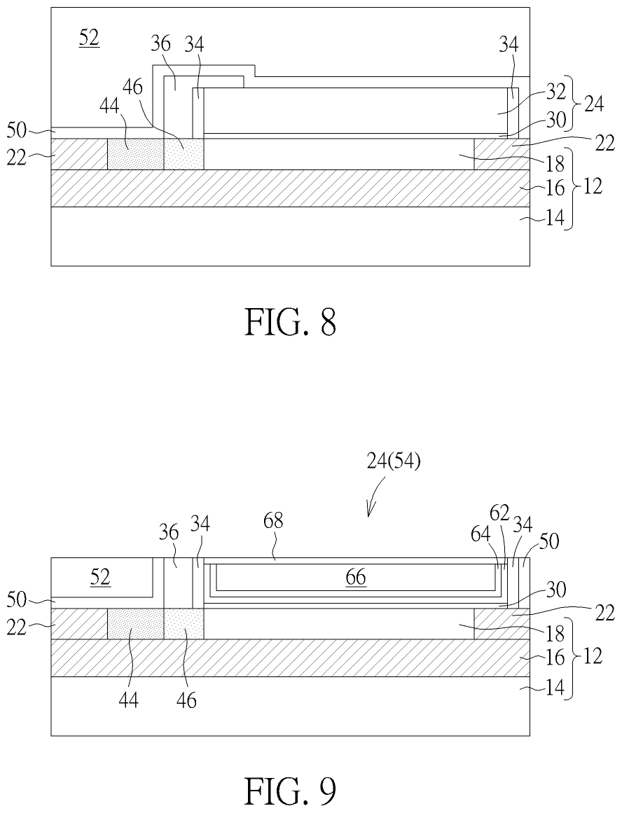

Referring to FIGS. 6-9, FIG. 6 illustrates a top view for fabricating a RF device following FIG. 5, the left portion of FIG. 7 illustrates a cross-section view of FIG. 6 taken along the sectional line AA′, the right portion of FIG. 7 illustrates a cross-section view of FIG. 6 taken along the sectional line BB′, and FIGS. 8-9 illustrate cross-section views for fabricating the RF device following FIG. 7. It should be noted that as shown on the left portion of FIG. 7, after being implanted with p-type dopants, part of the p-type dopants within the body region 44 would diffuse toward right side of the substrate 12 to form another region 46 with slightly lower concentration of p-type dopants in the substrate 12 directly under the dielectric layer 36 and the spacer 34. As shown on the right portion of FIG. 7, after being implanted with n-type dopants, part of the n-type dopants within the source/drain region 40 would diffuse toward left side of the substrate 12 to form a region 48 with slightly lower concentration of n-type dopants in the substrate 12 directly under the dielectric layer 36.

Next, as shown in FIGS. 6-9, a selective salicide process could be conducted to form a silicide on the surface of the source/drain region 40 and the body region 44, a contact etch stop layer (CESL) 50 and an inter-layer dielectric (ILD) layer 52 could be formed around the gate structure 24 as shown in FIG. 8, a replacement metal gate (RMG) process could be conducted to transform the gate structure 24 into metal gate 54 as shown in FIG. 9, and then finally a contact plug formation could be conducted to form contact plugs 56 in the ILD layer 52 connecting the source/drain region 40 and the body region 44 as shown in FIG. 6.

Specifically, as shown in FIG. 8, a contact etch stop layer (CESL) 50 made of silicon nitride could be formed on the substrate 12 surface to cover the gate structure 24, the spacer 36, and the dielectric layer 36, and then an ILD layer 52 is formed on the CESL 50 afterwards.

Next, as shown in FIG. 9, a planarizing process such as a chemical mechanical polishing (CMP) process is conducted to remove part of the ILD layer 52, part of the CESL 50, and part of the dielectric layer 36 so that the top surfaces of the spacer 34, dielectric layer 36, CESL 50, and ILD layer 52 are coplanar.

Next, a replacement metal gate (RMG) process is conducted to transform the gate structure 24 into metal gate 54. For instance, the RMG process could be accomplished by first performing a selective dry etching or wet etching process using etchants including but not limited to for example ammonium hydroxide (NH₄OH) or tetramethylammonium hydroxide (TMAH) to remove the gate material layer 32 from gate structure 24 for forming a recess (not shown) in the ILD layer 52. Next, a high-k dielectric layer 62, a work function metal layer 64, and a low resistance metal layer 66 are formed in the recess, and a planarizing process such as CMP is conducted to remove part of low resistance metal layer 66, part of work function metal layer 64, and part of high-k dielectric layer 62 to form metal gate. In this embodiment, the gate structure 24 or metal gate 54 fabricated through high-k last process of a gate last process preferably includes an interfacial layer or gate dielectric layer 30, a U-shaped high-k dielectric layer 62, a U-shaped work function metal layer 64, and a low resistance metal layer 66 as the high-k dielectric layer 62, the work function metal layer 64, and the low resistance metal layer 66 together serving as a gate electrode for each transistor or each device.

In this embodiment, the high-k dielectric layer 62 is preferably selected from dielectric materials having dielectric constant (k value) larger than 4. For instance, the high-k dielectric layer 50 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 64 is formed for tuning the work function of the metal gate in accordance with the conductivity of the device. For an NMOS transistor, the work function metal layer 64 having a work function ranging between 3.9 eV and 4.3 eV may include titanium aluminide (TiAl), zirconium aluminide (ZrAl), tungsten aluminide (WAI), tantalum aluminide (TaAl), hafnium aluminide (HfAl), or titanium aluminum carbide (TiAIC), but it is not limited thereto. For a PMOS transistor, the work function metal layer 64 having a work function ranging between 4.8 eV and 5.2 eV may include titanium nitride (TIN), tantalum nitride (TaN), tantalum carbide (TaC), but it is not limited thereto. An optional barrier layer (not shown) could be formed between the work function metal layer 64 and the low resistance metal layer 66, in which the material of the barrier layer may include titanium (Ti), titanium nitride (TiN), tantalum (Ta) or tantalum nitride (TaN). Furthermore, the material of the low-resistance metal layer 66 may include copper (Cu), aluminum (Al), titanium aluminum (TiAl), cobalt tungsten phosphide (CoWP) or any combination thereof.

Next, part of the high-k dielectric layer 62, part of the work function metal layer 64, and part of the low resistance metal layer 66 are removed to form a recess (not shown), and a hard mask 68 is then formed into the recess so that the top surfaces of the hard mask 68 and ILD layer 52 are coplanar. The hard mask 68 could be made of material including but not limited to for example SiO₂, SiN, SION, SiCN, or combination thereof.

According to an embodiment of the present invention, the formation of the contact plugs 56 could be accomplished by first conducting a photo-etching process by using a patterned mask (not shown) as mask to remove part of the ILD layer 52 and part of the CESL 50 adjacent to the gate structure 24 for forming contact holes (not shown) exposing the source/drain region 40 and body region 44. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned barrier layer and low resistance metal layer for forming contact plugs 56 electrically connecting the source/drain region 40 and the body region 44. This completes the fabrication of a semiconductor device according to an embodiment of the present invention.

Referring to FIG. 9, FIG. 9 illustrates a structural view of a RF device according to an embodiment of the present invention. As shown in FIG. 9, the RF device includes a gate structure 24 disposed on the substrate 12, a spacer 34 adjacent to one side such as left side of the gate structure 24, a spacer 34 disposed on another side such as right side of the gate structure 24, a CESL 50 disposed adjacent to the left spacer 34, a CESL 50 disposed adjacent to the right spacer 34, a dielectric layer 36 disposed adjacent to one side such as left side of the gate structure 24, a body region 44 disposed in the substrate 12 adjacent to the dielectric layer 36, and an ILD layer 52 around the dielectric layer 36 and the gate structure 36. Preferably, the sidewall of the body region 44 on left side of the gate structure 24 is aligned with the sidewalls of the CESL 50 and the dielectric layer 36.

Specifically, the dielectric layer 36 is disposed between the left spacer 34 and the left CESL 50, no dielectric layer 36 is disposed between the right spacer 34 and the right CESL 50, hence the dielectric layer 36 is only disposed on one side of the gate structure 24. Preferably, the substrate 12 of this embodiment includes a SOI substrate so that the STI 22 is disposed in substrate 12 adjacent to two sides of the gate structure 24, in which the left STI 22 is disposed under the CESL 50 and the ILD layer 52 while the right STI 22 is disposed under the gate structure 24, the spacer 34, and the CEL 50 at the same time.

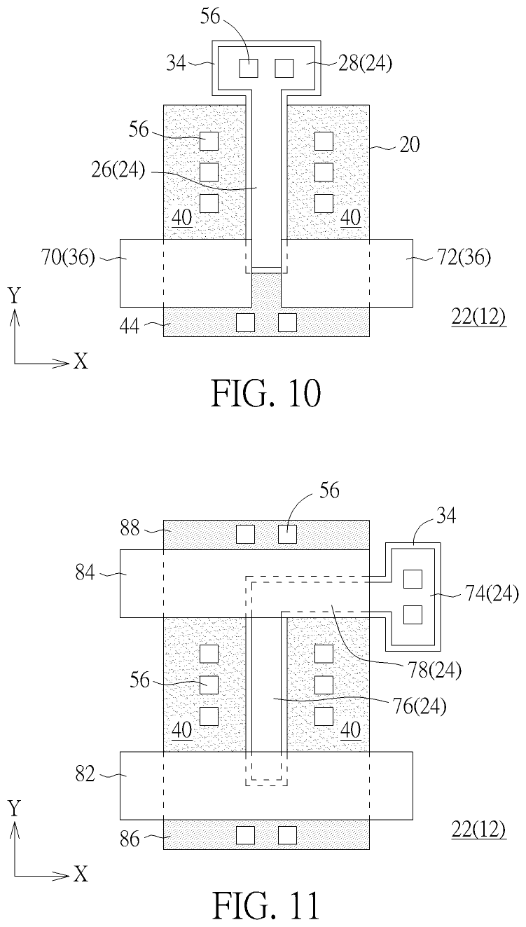

Referring to FIG. 10, FIG. 10 illustrates a top view of a RF device according to an embodiment of the present invention. As shown in FIG. 10, in contrast to the dielectric layer 36 in FIG. 6 is extending along the X-direction continuously across the source/drain region 40 and the gate structure 24, the dielectric layer 36 of this embodiment is divided into two portions, in which the first portion 70 is disposed adjacent to one side such as left side of the gate structure 24 between the source/drain region 40 and the body region 44 and the second portion 72 is disposed on another side such as right side of the gate structure 24 between the source/drain region 40 and the body region 44. Preferably, the first portion 70 and the second portion 72 are symmetrical thereby having same lengths, same widths, and same area.

Referring to FIG. 11, FIG. 11 illustrates a top view of a RF device according to an embodiment of the present invention. As shown in FIG. 11, in contrast to the gate structure 24 shown in FIG. 6 includes a T-shape, the gate structure 24 of this embodiment preferably adds another twist or turning portion to the original vertical portion of the T-shape structure so that the new gate structure 24 now includes a first vertical portion 74, a second vertical portion 76, and a horizontal portion 78 connecting the first vertical portion 74 and the second vertical portion 76. Moreover, in contrast to the structure shown in FIG. 6, only includes a single dielectric layer 36 and a single body region 44, the RF device of this embodiment includes two dielectric layers 82, 84 and two body region regions 86, 88, in which the body region 86 is disposed below the source/drain region 40, another body region 88 is disposed above the source/drain region 40, the lower dielectric layer 82 is disposed between the body region 86 and the second vertical portion 76, and the upper dielectric layer 84 is extending along the X-direction between the horizontal portion 78 and the body region 88 while overlapping the horizontal portion 78 and the source/drain region 40.

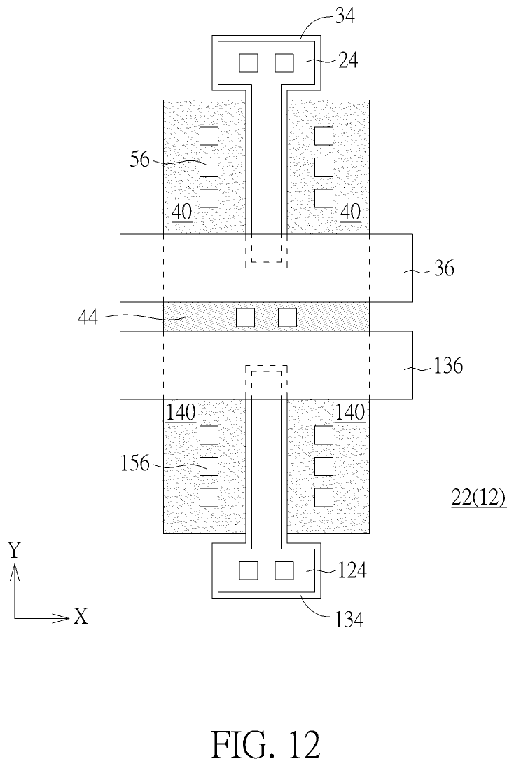

Referring to FIG. 12, FIG. 12 illustrates a top view of a RF device according to an embodiment of the present invention. As shown in FIG. 12, it would also be desirable to form mirror-image or symmetrical structures including a gate structure 124, a spacer 134, a dielectric layer 136, a source/drain region 140, and contact plugs 156 below the body region 44 as shown in FIG. 6, in which the body region 44 in this instance preferably serving as a common body region 44. Preferably, the material and position of the gate structure 124, the spacer 134, the dielectric layer 136, the source/drain region 140, and the contact plugs 156 all correspond to the material and position of the gate structure 24, the spacer 34, the dielectric layer 36, the source/drain region 40, and the contact plugs 56 as shown in FIG. 6. For instance, the gate structure 124 is extending along the Y-direction on the substrate 12, the source/drain region 140 is disposed adjacent to two sides of the gate structure 124, and the dielectric layer 136 extending between the gate structure 124 and the body region 44.

Overall, the present invention provides a novel RF device structure which in the top view of FIG. 6 for instance places a dielectric layer 36 between the tail end of the T-shape gate structure 24 and the body region 44. By doing so, as shown in the cross-section view of FIG. 7, the region 48 below the dielectric layer 36 would not be having any depletion region or any gate field so that electron holes directly under the gate structure could be easily expelled outside. According to a preferred embodiment of the present invention, this design not only lowers resistance and parasitic capacitance of the device, but also reduces floating body effects and improves overall performance of the device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A radio-frequency (RF) device, comprising:
a first gate structure extending along a first direction on a substrate;
a first source/drain region adjacent to two sides of the first gate structure; and
a first body region extending along a second direction opposite to the first gate structure.

2. The RF device of claim 1, further comprising a spacer around the first gate structure.

3. The RF device of claim 1, wherein the first gate structure comprises a T-shape.

4. The RF device of claim 3, wherein the T-shape comprises a vertical portion and a horizontal portion.

5. The RF device of claim 4, wherein the first body region is opposite to the vertical portion.

6. The RF device of claim 1, wherein the first body region and the first source/drain region comprise different conductive type.

7. The RF device of claim 1, further comprising a first dielectric layer extending along the second direction between the first gate structure and the first body region.

8. The RF device of claim 7, wherein the first dielectric layer comprises:
a first portion adjacent to one side of the first gate structure and between the first source/drain region and the first body region; and
a second portion adjacent to another side of the first gate structure and between the first source/drain region and the first body region.

9. The RF device of claim 7, wherein the first gate structure comprises a first vertical portion, a second vertical portion, and a horizontal portion connecting the first vertical portion and the second vertical portion, the RF device further comprising:
the first dielectric layer between the first body region and the second vertical portion;
a second body region adjacent to the horizontal portion; and
a second dielectric layer extending along the second direction between the horizontal portion and the second body region.

10. The RF device of claim 7, further comprising:
a second gate structure extending along the first direction on the substrate;
a second source/drain region adjacent to two sides of the second gate structure; and
a second dielectric layer extending between the second gate structure and the first body region.

11. The RF device of claim 1, wherein the substrate comprises a silicon-on-insulator (SOI) substrate.

12. A radio-frequency (RF) device, comprising:
a gate structure on a substrate;
a dielectric layer adjacent to one side of the gate structure;
a body region adjacent to the dielectric layer in the substrate; and
an interlayer dielectric (ILD) layer around the dielectric layer and the gate structure.

13. The RF device of claim 12, further comprising:
a first spacer adjacent to one side of the gate structure;
a second spacer adjacent to another side of the gate structure;
a first contact etch stop layer (CESL) adjacent to first spacer;
a second CESL adjacent to the second spacer;
the dielectric layer between the first spacer and the first CESL; and
the ILD layer around the first CESL and the second CESL.

14. The RF device of claim 13, further comprising a shallow trench isolation (STI) under the gate structure.

15. The RF device of claim 14, wherein the STI is under the second spacer and the second CESL.

16. The RF device of claim 13, wherein a sidewall of the body region is aligned with a sidewall of the first CESL.

17. The RF device of claim 12, wherein a sidewall of the body region is aligned with a sidewall of the dielectric layer.

18. The RF device of claim 12, wherein the gate structure comprises a metal gate.

19. The RF device of claim 12, wherein the substrate comprises a silicon-on-insulator (SOI) substrate.
